(19) United States
(12) Patent Application Publication
(10) Pub. No.: US 2025/0194250 A1
(43) Pub. Date: Jun. 12, 2025

(54) TRANSISTOR BACKPLANE STRUCTURE

(71) Applicant: E Ink Holdings Inc., Hsinchu (TW)

(72) Inventors: Chao Feng Sung, Hsinchu (TW); Chen Chu Tsai, Hsinchu (TW)

(73) Assignee: E Ink Holdings Inc., Hsinchu (TW)

(21) Appl. No.: 18/817,226

(22) Filed: Aug. 28, 2024

(30) Foreign Application Priority Data
Dec. 8, 2023 (TW) 112147817

(51) Int. Cl. H01L 27/12

(52) U.S. Cl. CPC H10D 86/60; H10D 86/443; H10D 86/451; H10D 86/481

(57) ABSTRACT

A transistor backplane structure includes multiple pixel structures and a wire distribution layer. Each of the pixel structures includes a substrate, a transistor disposed on the substrate, and a first insulation layer disposed on the transistor. Multiple conductive vias are disposed in the first insulation layer. The wire distribution layer is disposed on the pixel structures. The stretchable electrode layer at a side of the wire distribution layer away from the pixel structure is connected to a contact of the transistor of the pixel structure through a conductive via in the first insulation layer of the pixel structure to form a pixel electrode.

### CROSS-REFERENCE TO RELATED APPLICATION

This application claims the priority benefit of Taiwan application serial no. 112147817, filed on Dec. 8, 2023. The entirety of the above-mentioned patent application is hereby incorporated by reference herein and made a part of this specification.

### BACKGROUND

### Technical Field

This disclosure relates to a display backplane structure, and in particular to a transistor backplane structure.

### Description of Related Art

With the advancement of technology, various display media are widely used in various display applications, such as TVs, laptops, e-paper books, mobile phones, large advertising signboards, and electronic labels in stores, etc. Among them, electrophoretic display (EPD) has excellent features such as light weight, thinness, and low power consumption.

Recently, flexible substrates have been used to develop flexible display devices that can be folded or rolled up, and can also be designed to be flexible and unbreakable, and can be made to stretch or shrink in a specific direction, so that the display device can be stretched to form a variety of shapes. One of the key modules to enable electronic paper to display different patterns is the stretchable and three-dimensional shaping thin film transistor backplane, which is used to drive electrophoretic display media as the next-generation electronic paper product. However, in general, display panels include display media and thin film transistor backplane, and traditional thin film transistor backplane is not stretchable, making it impossible to have stretchable and three-dimensional shaping properties when integrated with a stretchable display medium (such as an electrophoretic display panel). On the other hand, the relative geometries of the gate, source, and drain of the thin film transistor backplane affect the electrical performance. Thus, it is necessary to improve how to maintain consistent electrical properties after stretching.

### SUMMARY

The disclosure provides a transistor backplane structure, capable of achieving an effect of stretchable deformation while ensuring electrical properties of a transistor.

An embodiment of the disclosure proposes a transistor backplane structure, including multiple pixel structures and a wire distribution layer. Each of the pixel structure includes a substrate, a transistor disposed on the substrate, and a first insulation layer disposed on the transistor. Multiple conductive vias are disposed in the first insulation layer. The wire distribution layer is disposed on the pixel structures. The wire distribution layer includes multiple stretchable electrode layers and multiple stretchable insulation layers. The stretchable electrode layers are connected to a gate and a source of the transistor of the pixel structure through the conductive vias of the first insulation layer of the each of the pixel structures, and the stretchable electrode layer at a side of the wire distribution layer away from the pixel structure is connected to a contact of the transistor of the pixel structure through a conductive via in the first insulation layer of the pixel structure to form a pixel electrode.

In the transistor backplane structure of the embodiment of the disclosure, the transistor is disposed on the substrate and connected to the stretchable electrode layer through the conductive via, and the wire distribution layer includes the stretchable electrode layer and the stretchable insulation layer. Such a design allows the substrate to protect the transistor from being damaged due to deformation. On the other hand, an area of the wire distribution layer where the substrate is not disposed may have an effect of stretching deformation. Thus, the transistor backplane structure of the embodiment of the disclosure may achieve the effect of stretchable deformation while ensuring the electrical properties of the transistor.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate example embodiments of the disclosure and, together with the description, serve to explain the principles of the disclosure.

FIG. 1 is a schematic cross-sectional view of an electrophoretic display panel according to an embodiment of the disclosure.

FIG. 2 is a top view of a pixel structure in a transistor backplane structure of FIG. 1.

FIG. 3 is a schematic cross-sectional view of a transistor backplane structure according to another embodiment of the disclosure.

FIG. 4A is a top view of a pixel structure in the transistor backplane structure of FIG. 3.

FIG. 4B is a top view of the pixel structure of FIG. 4A with a grounded stretchable electrode layer disposed thereon.

FIG. 4C is a top view of the pixel structure of FIG. 4A with a stretchable electrode layer electrically connected to a contact.

FIG. 5 is a schematic cross-sectional view of an electrophoretic display panel according to still another embodiment of the disclosure.

FIG. 6 is a schematic cross-sectional view of an electrophoretic display panel according to yet another embodiment of the disclosure.

### DESCRIPTION OF THE EMBODIMENTS

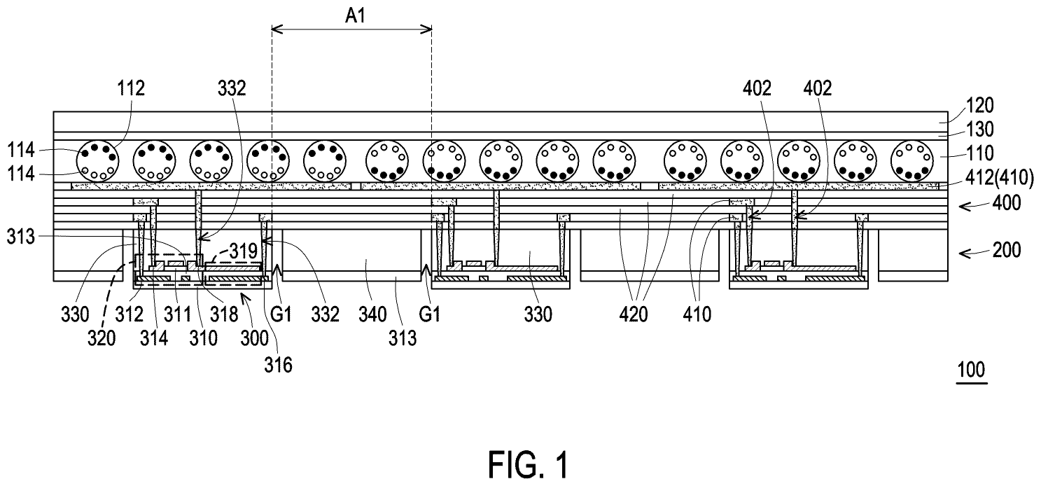

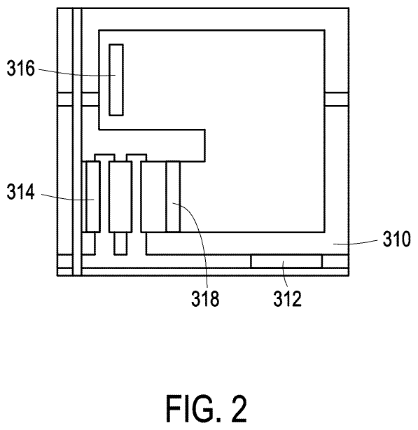

FIG. 1 is a schematic cross-sectional view of an electrophoretic display panel according to an embodiment of the disclosure, and FIG. 2 is a top view of a pixel structure in a transistor backplane structure of FIG. 1. Referring to FIG. 1 and FIG. 2, an electrophoretic display panel 100 of this embodiment includes a transistor backplane structure 200, a stretchable display medium layer 110, and a stretchable substrate 120. The transistor backplane structure 200 includes multiple pixel structures 300 and a wire distribution layer 400. The pixel structures 300 may be arranged in an array, for example, in a two-dimensional array. Each of the pixel structures 300 includes a substrate 310, a transistor 320 disposed on the substrate 310, and a first insulation layer 330 disposed on the transistor 320. Multiple conductive vias 332 are disposed in the first insulation layer 330. In this embodiment, the transistor 320 is, for example, a thin film transistor (TFT).

The wire distribution layer 400 is disposed on the pixel structures 300. The wire distribution layer 400 includes multiple stretchable electrode layers 410 and multiple stretchable insulation layers 420. In this embodiment, the stretchable insulation layers 420 separate the stretchable electrode layers 410, so that the stretchable electrode layers 410 are electrically insulated from each other. The stretchable electrode layers 410 are connected to a gate 312 and a source 314 of the transistor 320 of the pixel structure 300 through the conductive vias 332 in the first insulation layer 330 of the each of the pixel structures 300. In this embodiment, the stretchable electrode layers 410 connect the gate 312 and the source 314 of the transistor 320 of the pixel structure 300 to a driving circuit through the conductive vias 332 in the first insulation layer 330 of the each of the pixel structures 300 to drive. In addition, the stretchable electrode layer 412 at a side of the wire distribution layer 400 away from the pixel structure 300 is connected to a contact 318 of the transistor 320 of the pixel structure 300 through a conductive via 332 in the first insulation layer 330 of the pixel structure 300 to form a pixel electrode. In this embodiment, the stretchable electrode layer 412 of the wire distribution layer 400 is respectively connected to the conductive via 332 in the first insulation layer 330 through multiple conductive vias 402 in the wire distribution layer 400, so that the gate electrode 312 and the source electrode 314 are electrically connected to the stretchable electrode layer 412 through the conductive via 332 and the conductive via 402, respectively, and are further electrically connected to the driving circuit. On the other hand, the stretchable electrode layer 412 is electrically connected to the contact 318 through the connected conductive via 402 and the conductive via 332.

In this embodiment, a material of the transistor 320 includes amorphous silicon, polycrystalline silicon, oxide semiconductor material, organic semiconductor material, or a combination thereof. In addition, in this embodiment, the transistor 320 further includes a channel layer 311 (which is a semiconductor layer) and a gate insulation layer 313. The channel layer 311 is connected between the source 314 and the contact 318, and the gate 312 extends to one side of the channel layer 311. The gate insulation layer 313 is disposed between the channel layer 311 and the gate 312 to electrically insulate the gate 312 from the channel layer 311. Conductivity of the channel layer 311 may be controlled by applying a voltage to the gate 312. In this embodiment, the each of the pixel structures 300 further includes a storage capacitor 319 disposed on the substrate 310. The storage capacitor 319 is electrically connected between the contact 318 and a ground terminal 316, and the first insulation layer 330 is disposed on the storage capacitor 319. In this embodiment, one of the stretchable electrode layers 410 is connected to the ground terminal 316 of the storage capacitor 319 through a conductive via 402 in the wire distribution layer 400 and one of the conductive vias 332 in the first insulation layer 330 of the each of the pixel structures 300 connected thereto. In this way, the ground terminal may be electrically connected to a ground terminal of the driving circuit. In addition, in this embodiment, a material of the gate insulation layer 313 may be an organic insulating material or an inorganic insulating material.

The stretchable display medium layer 110 is disposed on the stretchable substrate 120 and the transistor backplane structure 200. The stretchable display medium layer 110 is, for example, an electrophoretic display medium layer, which may include a capsule 112 and electrophoretic particles 114 disposed in the capsule 112. A common electrode layer 130 may be disposed between the stretchable display medium layer 110 and the stretchable substrate 120. When the driving circuit applies voltage to the gate 312, the source 314, and the common electrode layer 130, a voltage difference is generated between the stretchable electrode layer 412 and the common electrode layer 130, which in turn changes a distribution state of the electrophoretic particles 114 in the capsule 112, and achieves various expected display effects. Thus, the wire distribution layer 400 may also be regarded as an interposer. In this embodiment, the stretchable display medium layer 110, the common electrode layer 130, and the stretchable substrate 120 are all made of stretchable and deformable materials.

In this embodiment, Young's modulus of the first insulation layer 330 is smaller than Young's modulus of the substrate 310. In addition, in this embodiment, Young's modulus of the stretchable electrode layers 410 and Young's modulus of the stretchable insulation layer 420 are both smaller than the Young's modulus of the substrate 310. That is, the substrate 310 is relatively hard and is relatively difficult to be stretched or deformed, thus effectively protecting the transistor 320 located thereon. On the other hand, the stretchable electrode layers 410 and the stretchable insulation layers 420 are relatively soft and susceptible to being stretched or deformed, so an area A1 of the wire distribution layer 400 where the transistor 320 is not disposed is a stretchable area, so as to enable the transistor backplane structure 200 and the electrophoretic display panel 100 to achieve the effect of stretchable deformations. In this embodiment, a material of the substrate 310 is, for example, polyimide or other materials with a higher Young's modulus.

In the transistor backplane structure 200 of this embodiment, the transistor 320 is disposed on the substrate 310 and connected to the stretchable electrode layer 410 through the conductive via 332, and the wire distribution layer 400 includes the stretchable electrode layer 410 and the stretchable insulation layer 420. Such a design allows the substrate 310 to protect the transistor 320 from being damaged due to deformation. On the other hand, the area A1 of the wire distribution layer 400 where the substrate 310 is not disposed may have an effect of stretching deformation. Thus, the transistor backplane structure 200 of the embodiment of the disclosure may achieve the effect of stretchable deformation while ensuring the electrical properties of the transistor 320. That is, the transistor backplane structure 200 of this embodiment is adapted to being stretched and three-dimensionally shaped, and may be used in different applications, but may be stretched and three-dimensionally shaped without damaging the transistor 320, which in turn may be stabilized to drive the stretchable display medium layer 110.

In this embodiment, a second insulation layer 340 is disposed between the adjacent pixel structures 300, and a gap G1 is between the second insulation layer 340 and the adjacent pixel structures 300. In addition, Young's modulus of the second insulation layer 340 is smaller than the Young's modulus of the substrate 310. In this embodiment, multiple substrates 310 of the pixel structures 300 are respectively disposed on multiple first insulation layers 330 of the pixel structures 300, but are not disposed on multiple second insulation layers 340 between the first insulation layers 330. In fabricating the pixel structure 300 and the second insulation layer 340, an insulation layer may be formed on a large area of substrate, and then the gap G1 is cut between the large area of the substrate and the insulation layer. A portion of the insulation layer and a portion of the substrate therebelow form the pixel structures 300, while another portion of the insulation layer forms the second insulation layer 340, and by subsequently removing the portion of the substrate below the second insulation layer 340, and the transistor backplane structure 200 of FIG. 1 is formed. The gap G1 is designed so that the main deformation and stretching area A1 is determined by the wire distribution layer 400 to solve the problem of the substrate 310 being difficult to stretch. In this embodiment, the gate insulation layer 313 may cover lower surfaces of the first insulation layer 330 and the second insulation layer 340, and a portion of the gate insulation layer 313 overlying the first insulation layer 330 is separated from a portion of the gate insulation layer 313 overlying the second insulation layer 340 by a gap G1. In another embodiment, the gate insulation layer 313 may also exist only on the lower surface of the first insulation layer 330, that is, only exist in the pixel structure 300, and not exist on the lower surface of the second insulation layer 340.

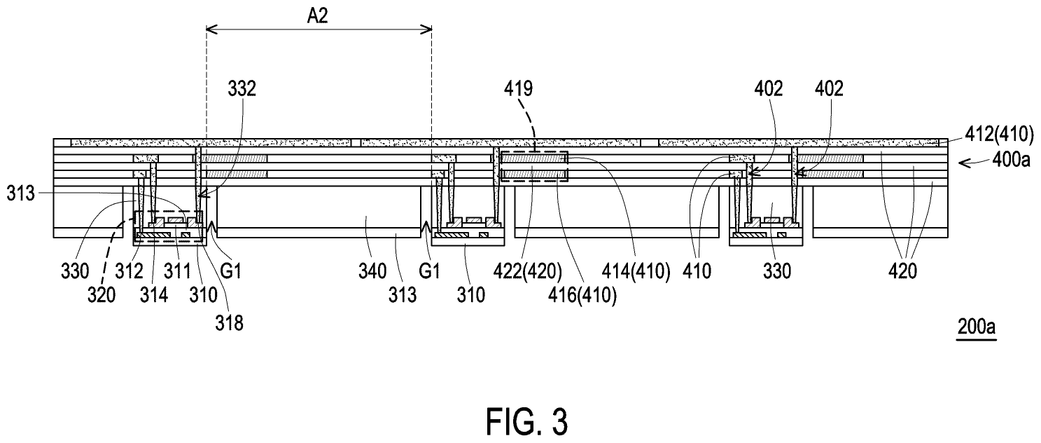

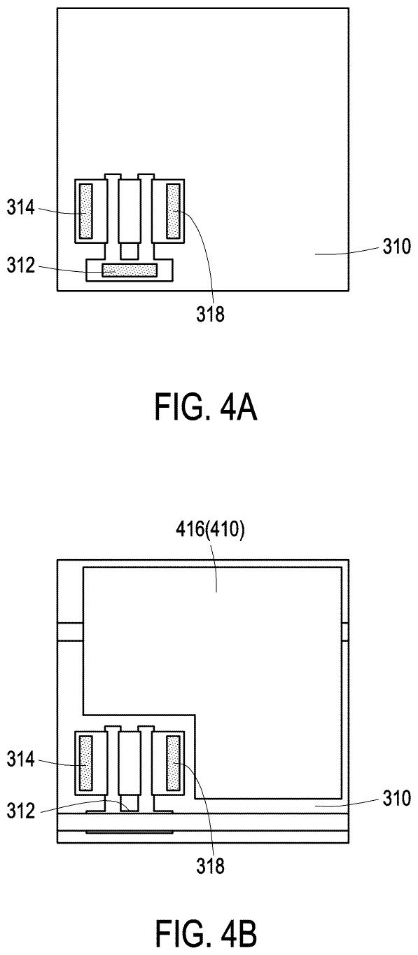

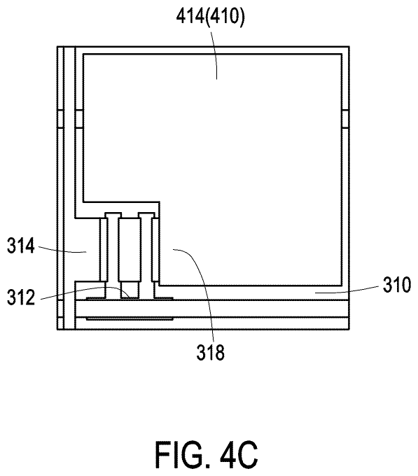

FIG. 3 is a schematic cross-sectional view of a transistor backplane structure according to another embodiment of the disclosure. FIG. 4A is a top view of a pixel structure in the transistor backplane structure of FIG. 3. FIG. 4B is a top view of the pixel structure of FIG. 4A with a grounded stretchable electrode layer disposed thereon. FIG. 4C is a top view of the pixel structure of FIG. 4A with a stretchable electrode layer electrically connected to a contact. Referring to FIG. 3 and FIG. 4A to FIG. 4C, a transistor backplane structure 200a of this embodiment is similar to the transistor backplane structure 200 of FIG. 1, and the main differences between the two are as follows. In the transistor backplane structure 200a of this embodiment, two of the stretchable electrode layers 410 of a wire distribution layer 400a (e.g., a stretchable electrode layer 414 and a stretchable electrode layer 416) and a stretchable insulation layer 422 between the two layers form a storage capacitor 419. Compared with the embodiment of FIG. 1, the storage capacitor 419 is moved to the wire distribution layer 400a in this embodiment, which effectively reduces the area occupied by the substrate 310, and thus enlarges the area of a stretchable area A2 (i.e., the area without the substrate 310) (it can be clearly seen that the area A2 in FIG. 3 is larger than the area A1 in FIG. 1). In this way, the transistor backplane structure 200a of this embodiment may be more adapted to stretching and deformation.

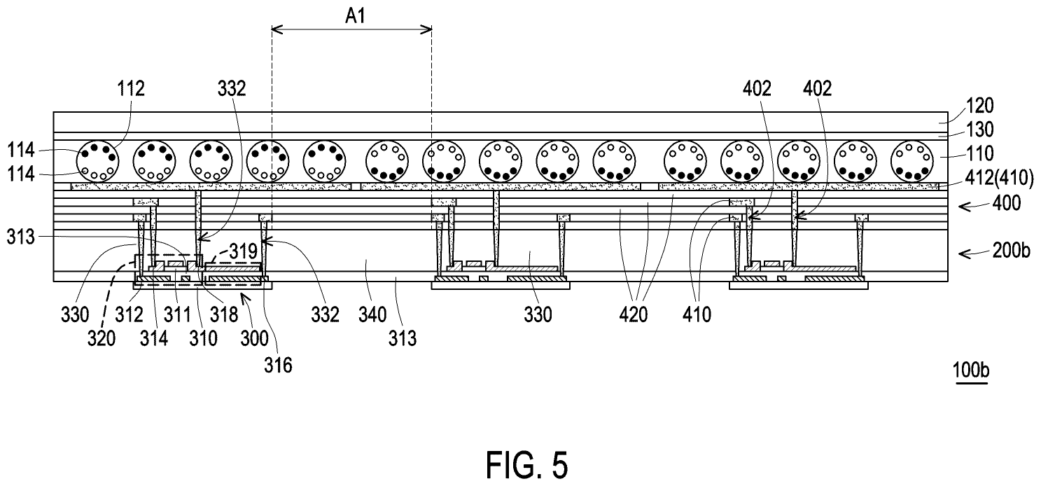

FIG. 5 is a schematic cross-sectional view of an electrophoretic display panel according to still another embodiment of the disclosure. Referring to FIG. 5, an electrophoretic display panel 100b of this embodiment is similar to the electrophoretic display panel 100 of FIG. 1, and the main differences between the two are as follows. In a transistor backplane structure 200b of the electrophoretic display panel 100b of this embodiment, the first insulation layer 330 and the second insulation layer 340 are connected as a whole without the gap G1 between them as shown in FIG. 1. In addition, the gate insulation layer 313 on the lower surface of the first insulation layer 330 is also connected to the gate insulation layer 313 on the lower surface of the second insulation layer 340 without the gap G1 between them as shown in FIG. 1. Although there is no gap G1 in this embodiment, the material of the substrate 310 below the second insulation layer 340 has been removed, so the remaining second insulation layer 340 and the gate insulation layer 313 are flexible and stretchable. Thus, the area A1 may still form a stretchable area.

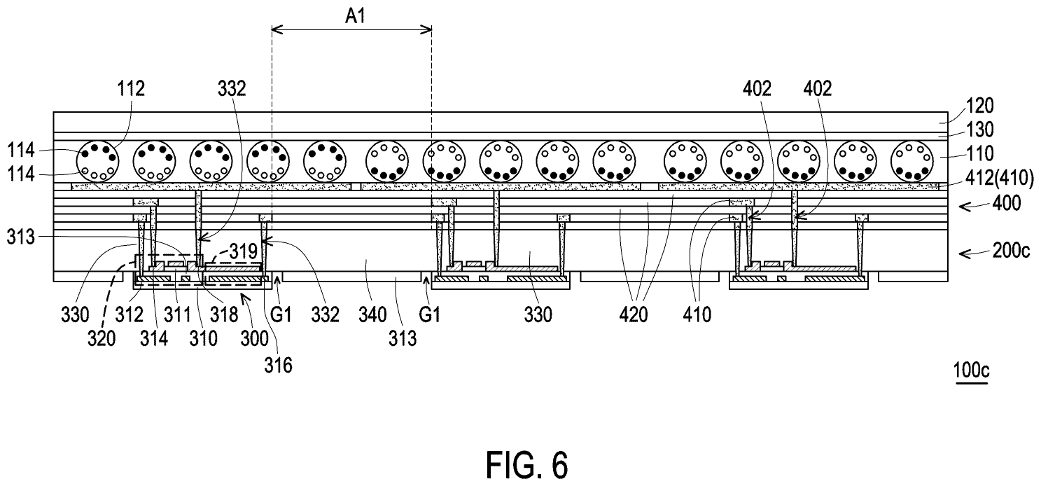

FIG. 6 is a schematic cross-sectional view of an electrophoretic display panel according to yet another embodiment of the disclosure. Referring to FIG. 6, an electrophoretic display panel 100c of this embodiment is similar to the electrophoretic display panel 100b of FIG. 5, and the main differences between the two are as follows. In a transistor backplane structure 200c of the electrophoretic display panel 100c of this embodiment, the first insulation layer 330 and the second insulation layer 340 are connected as a whole without the gap G1 between them as shown in FIG. 1, but the gate insulation layer 313 on the lower surface of the first insulation layer 330 is disconnected from the gate insulation layer 313 on the lower surface of the second insulation layer 340 and there is a gap G1 between them, so that the area A1 may still be formed into a stretchable area.

To sum up, in the transistor backplane structure of the embodiment of the disclosure, the transistor is disposed on the substrate and connected to the stretchable electrode layer through the conductive via, and the wire distribution layer includes the stretchable electrode layer and the stretchable insulation layer. Such a design allows the substrate to protect the transistor from being damaged due to deformation. On the other hand, an area of the wire distribution layer where the substrate is not disposed may have an effect of stretching deformation. Thus, the transistor backplane structure of the embodiment of the disclosure may achieve the effect of stretchable deformation while ensuring the electrical properties of the transistor.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A transistor backplane structure, comprising:
a plurality of pixel structures, wherein each of the pixel structures comprises a substrate, a transistor disposed on the substrate, and a first insulation layer disposed on the transistor, wherein a plurality of conductive vias are disposed in the first insulation layer; and
a wire distribution layer, disposed on the pixel structures, wherein the wire distribution layer comprises a plurality of stretchable electrode layers and a plurality of stretchable insulation layers, the stretchable electrode layers are connected to a gate and a source of the transistor of the pixel structure through the conductive vias of the first insulation layer of the each of the pixel structures, and the stretchable electrode layer at a side of the wire distribution layer away from the pixel structure is connected to a contact of the transistor of the pixel structure through a conductive via in the first insulation layer of the pixel structure to form a pixel electrode.

2. The transistor backplane structure according to claim 1, wherein Young's modulus of the first insulation layer is smaller than Young's modulus of the substrate.

3. The transistor backplane structure according to claim 1, wherein Young's modulus of the stretchable electrode layers and Young's modulus of the stretchable insulation layers are both smaller than Young's modulus of the substrate.

4. The transistor backplane structure according to claim 1, wherein a second insulation layer is disposed between the adjacent pixel structures, and a gap is between the second insulation layer and the adjacent pixel structure.

5. The transistor backplane structure according to claim 4, wherein Young's modulus of the second insulation layer is smaller than Young's modulus of the substrate.

6. The transistor backplane structure according to claim 4, wherein a plurality of substrates of the pixel structures are respectively disposed on the first insulation layers of the pixel structures, but are not disposed on a plurality of second insulation layers between the first insulation layers.

7. The transistor backplane structure according to claim 1, wherein the each of the pixel structures further comprises a storage capacitor disposed on the substrate, and the first insulation layer is disposed on the storage capacitor.

8. The transistor backplane structure according to claim 7, wherein one of the stretchable electrode layers is connected to a ground terminal of the storage capacitor through one of the conductive vias in the first insulation layer of the each of the pixel structures.

9. The transistor backplane structure according to claim 1, wherein two of the stretchable electrode layers and a stretchable insulation layer between the two layers form a storage capacitor.

10. The transistor backplane structure according to claim 1, wherein a material of the transistor comprises amorphous silicon, polycrystalline silicon, oxide semiconductor material, organic semiconductor material, or a combination thereof.
